(19) United States
(12) Patent Application Publication
(10) Pub. No.: US 2026/0098338 A1
(43) Pub. Date: Apr. 9, 2026

(54) MULTIPLE PORT GAS INJECTION AND EXHAUST FOR BATCH SUBSTRATE PROCESSING CHAMBER

(71) Applicant: Applied Materials, Inc., Santa Clara, CA (US)

(72) Inventors: Andrew Nguyen, Gilbert, AZ (US); Vijayabhaskara Venkatagiriyappa, Bangalore (IN); Sue-Ann Yow, Mesa, AZ (US); Eric Liu, Tempe, AZ (US); ChiaoYuan Cheng, Santa Clara, CA (US); Dhivanraj Subramanian, Chennai (IN)

(73) Assignee: Applied Materials, Inc., Santa Clara, CA (US)

(21) Appl. No.: 18/909,061

(22) Filed: Oct. 8, 2024

(51) Int. Cl. C23C 16/455; C23C 16/52

(52) U.S. Cl. CPC C23C 16/45544; C23C 16/52

(57) ABSTRACT

Processing chambers having a chamber body with a wafer cassette assembly and at least one lift pin assembly are described. The wafer cassette assembly has at least two support columns configured to hold a plurality of wafer supports spaced along a height of the support columns. The lift pin assemblies have a plurality of lift pins arranged so that each of the plurality of wafer supports comprises at least three lift pins.

### TECHNICAL FIELD

Embodiments of the disclosure are directed to apparatus and methods for depositing films on a wafer. In particular, embodiments of the disclosure are directed to batch wafer processing atomic layer deposition (ALD) chambers that provides uniform deposition on the wafers.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. To increase production yields, batch processing chambers have been developed that can process multiple wafers at one time.

Some batch processing chambers use a flow of reactive gas across the surfaces of multiple wafers. Current batch processing chambers allow films to be deposited on the front side and back side of the wafer. FIG. 1A illustrates a cross-sectional schematic view of a prior art vertically stacked batch processing chamber 10. FIG. 1B illustrates a top view of the vertically stacked batch substrate (or wafer) processing chamber 10 of FIG. 1A showing the flow of gases in the chamber. In the vertically stacked batch processing chambers 10, wafers 12 are positioned on supports 14 in a spaced apart arrangement. A gas 16 is injected into the wafer processing chamber 10 from a gas inlet 18 including a first gas inlet port 18a and a second gas inlet port 18b, causing a first gas and a second gas to flow across the surface of the wafers 12, as illustrated in FIG. 1B. This type of gas injection deposits a film on the top surface 12a of the wafer 12, however, non-uniformity of the deposited films across the surface of each of the wafers 12 in vertically stacked batch processing chambers 10 tends to be higher and does not meet film uniformity specifications compared to deposition uniformity achieved in single wafer vapor deposition chambers.

Accordingly, there is a need in the art for apparatus and methods for the batch deposition of films on a wafer more uniform deposition across the top surface 12a of the wafers.

### SUMMARY

One or more embodiments of the disclosure are directed to wafer processing chambers configured to deposit a film on a plurality of wafers. In one or more embodiments, a wafer processing chamber comprises a chamber body having a top, sidewall and bottom defining an inner chamber region and an outer chamber region; a wafer cassette assembly inside the chamber body, the wafer cassette assembly defining a peripheral surface 131 and a stack comprising at least two support columns configured to hold a number of wafer supports spaced along a height of the at least two support columns; and a first multiple level gas injection assembly located at a first peripheral location of the wafer cassette assembly and comprising a number of gas injection levels including a first gas injection level including a first gas manifold configured to inject a first process gas to a first wafer support and a second gas injection level including a first gas manifold configured to inject the first process gas to a second wafer support.

In specific embodiments, the wafer processing chamber further comprises a second multiple level gas injection assembly located at a second peripheral location of the wafer cassette assembly and spaced apart from the first peripheral location, the second multiple level gas injection assembly comprising at least two gas injection levels including a first gas injection level including a first gas manifold configured to inject the first process gas to the first wafer support and a second gas injection level including a first gas manifold configured to inject the first process gas to the second wafer support. In more specific embodiments, the wafer processing chamber comprises a third multiple level gas injection assembly located at a third peripheral location of the wafer cassette assembly and spaced apart from the second peripheral location, the second multiple level gas injection assembly comprising at least two gas injection levels including a first gas injection level including a first gas manifold configured to inject the first process gas to the first wafer support and a second gas injection level including a first gas manifold configured to inject the first process gas at the second wafer support.

Another aspect of the disclosure comprises a method of forming a film on plurality of wafers simultaneously comprising flowing the first process gas through the first multiple level gas injection assembly of the wafer processing chamber described herein. In one or more embodiments, the method further comprises flowing the first process gas through the second multiple level gas injection assembly and the third multiple level gas injection assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate embodiments of this disclosure and are therefore not to be considered limiting of its scope, for the disclosure may admit to other equally effective embodiments.

FIG. 1A illustrates a cross-sectional schematic view of a prior art vertically stacked batch wafer processing chamber;

FIG. 1B illustrates a top view of the prior art vertically stacked batch processing chamber of FIG. 1A showing the flow of gases in the chamber;

FIG. 2 illustrates a schematic cross-sectional view of a vertically stacked batch wafer processing chamber according to one or more embodiments of the disclosure;

FIG. 3 illustrates a schematic cross-sectional view of a portion of a vertically stacked batch processing chamber illustrating gas flows according to one or more embodiments of the disclosure;

FIG. 4 shows a schematic top view of a vertically stacked batch wafer processing chamber illustrating loading/unloading of the wafers according to one or more embodiments of the disclosure;

FIG. 5 illustrates a schematic partial cross-sectional view of a wafer being lifted off the plurality of wafer supports by a lift pin according to one or more embodiments of the disclosure;

FIG. 6 illustrates a schematic top view a vertically stacked batch wafer processing chamber and a gas supply according to one or more embodiments of the disclosure;

FIG. 7 illustrates a top view of one of the plurality of stacked gas manifolds of the gas manifold assembly according to one or more embodiments of the disclosure;

FIG. 8 illustrates a partial isometric view of a plurality of stacked gas manifolds configured to deliver process gases to a vertically stacked batch wafer processing chamber according to one or more embodiments of the disclosure;

FIG. 9 illustrates an isometric view of one of a plurality of stacked gas manifolds of the gas manifold assembly;

FIG. 10 illustrates a partial isometric view of one of a plurality of stacked gas manifolds configured to deliver process gases to a vertically stacked batch wafer processing chamber according to one or more embodiments of the disclosure;

FIG. 11 illustrates an isometric view of the plurality of stacked gas manifolds of the gas manifold assembly according to one or more embodiments of the disclosure;

FIG. 12 illustrates an isometric view of gas channels in a one of the plurality of stacked gas manifolds of the gas manifold assembly according to one or more embodiments of the disclosure;

FIG. 13A illustrates a top view of gas flow configuration through one of the plurality of stacked gas manifolds of the gas manifold assembly according to one or more embodiments of the disclosure;

FIG. 13B illustrates a top view of an alternate gas flow configuration through one of the plurality of stacked gas manifolds of the gas manifold assembly according to one or more embodiments of the disclosure;

FIG. 13C illustrates a top view of another alternate gas flow configuration through one of the plurality of stacked gas manifolds of the gas manifold assembly according to one or more embodiments of the disclosure;

FIG. 13D illustrates a top view of another alternate gas flow configuration through one of the plurality of stacked gas manifolds of the gas manifold assembly according to one or more embodiments of the disclosure;

FIG. 14A illustrates a top view of gas flow configuration through one of the plurality of stacked gas manifolds of the gas manifold assembly according to one or more embodiments of the disclosure;

FIG. 14B illustrates a top view of an alternate gas flow configuration through one of the plurality of stacked gas manifolds of the gas manifold assembly according to one or more embodiments of the disclosure;

FIG. 14C illustrates a top view of another alternate gas flow configuration through one of the plurality of stacked gas manifolds of the gas manifold assembly according to one or more embodiments of the disclosure;

FIG. 14D illustrates a top view of another alternate gas flow configuration through one of the plurality of stacked gas manifolds of the gas manifold assembly according to one or more embodiments of the disclosure;

FIG. 14E illustrates a top view of an alternate gas flow configuration through one of the plurality of stacked gas manifolds of the gas manifold assembly according to one or more embodiments of the disclosure;

FIG. 14F illustrates a top view of another alternate gas flow configuration through one of the plurality of stacked gas manifolds of the gas manifold assembly according to one or more embodiments of the disclosure;

FIG. 14G illustrates a top view of another alternate gas flow configuration through one of the plurality of stacked gas manifolds of the gas manifold assembly according to one or more embodiments of the disclosure;

FIG. 14H illustrates a top view of an alternate gas flow configuration through one of the plurality of stacked gas manifolds of the gas manifold assembly according to one or more embodiments of the disclosure; and

FIG. 14I illustrates a top view of another alternate gas flow configuration through one of the plurality of stacked gas manifolds of the gas manifold assembly according to one or more embodiments of the disclosure.

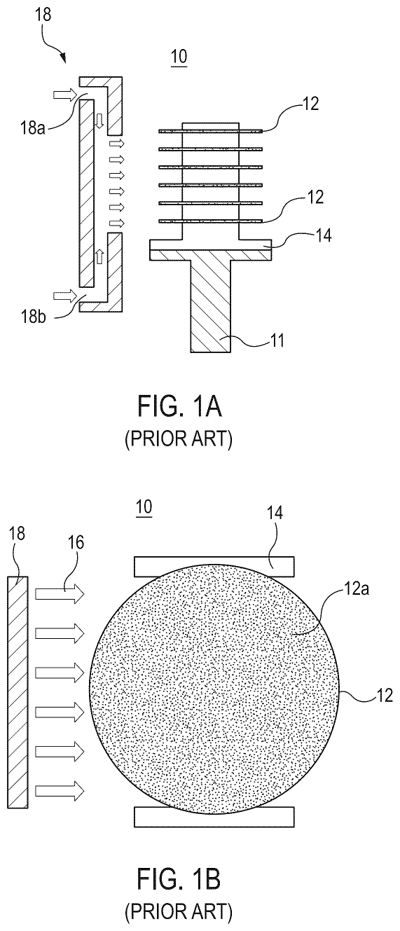

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” and a “wafer” as used herein, refers to any substrate, wafer or material surface formed on a substrate upon which film processing is performed during a fabrication process. For example, a substrate surface or wafer surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

One or more embodiments of the disclosure are directed to wafer batch processing chambers that provide more uniform deposition on the wafer compared to existing wafer batch processing chambers. Multiple gas injection ports to deliver gas to individual wafers in the batch processing chamber provides enhances full wafer coverage of the process gas and the film deposited on the wafers. In one or more embodiments, multiple gas exhaust ports for the batch process chamber are configured to nullify dead legs inside the chamber, minimizing unwanted deposition. According to some embodiments, complicated rotary mechanisms to rote the substrates during a deposition process are not required to provide more uniform deposition. According to one or more embodiments, wafer processing times are reduced. Fewer moving parts are needed compared to existing wafer batch processing chamber. In some embodiments, sequential operation of process gas inlet and outlets increase wafer deposition efficiency and uniformity. Control of process gas flows into the inlets that are peripherally spaced at different locations of the wafer processing chamber as well as gas outlets that are also peripherally spaced at different locations of the wafer processing chamber with the use of gas valves and a controller provides for strategic and precise gas flows to regulate process gas flow and improve deposition uniformity.

In some embodiments, the wafer cassette is designed to handle multiple wafers (e.g., 5 wafers, 6 wafers, 7, wafers 8 wafers 9 wafers, 10 wafers, 15 wafers, 20 wafers, 25 wafers or more than 25 wafers). Wafers are transferred to the cassette either singly by a single blade robot, or in batches using a multiple blade robot. The wafers are placed in a vertical pattern (stacking one above the other) on separate (individual) supports. The gas flow through the process chamber is across the surface of the wafers for deposition. In some embodiments, a single pin lift block is designed to lift all of the wafers in the cassette at the same time allowing for easier wafer hand-off. In some embodiments, a separate lift mechanism is designed for the wafer pedestal lift and pin lift and are integrated together.

In one or more embodiments, an integrated reservoir within each gas manifold will improve free flow of process gases with impacting gas flow conductance. The reservoir is configured to reduce any gas flow surges or back pressure that may develop during a film formation operation on a batch of wafers, for example during a chemical vapor deposition process or atomic layer deposition process.

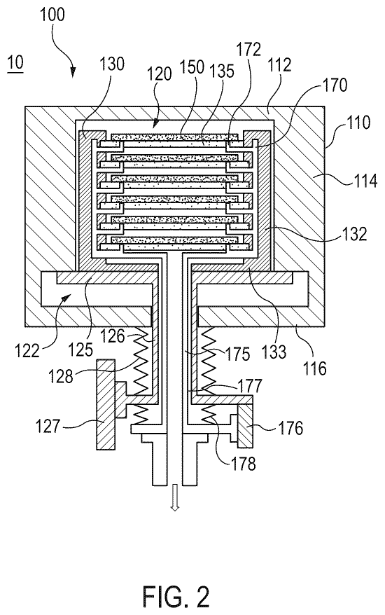

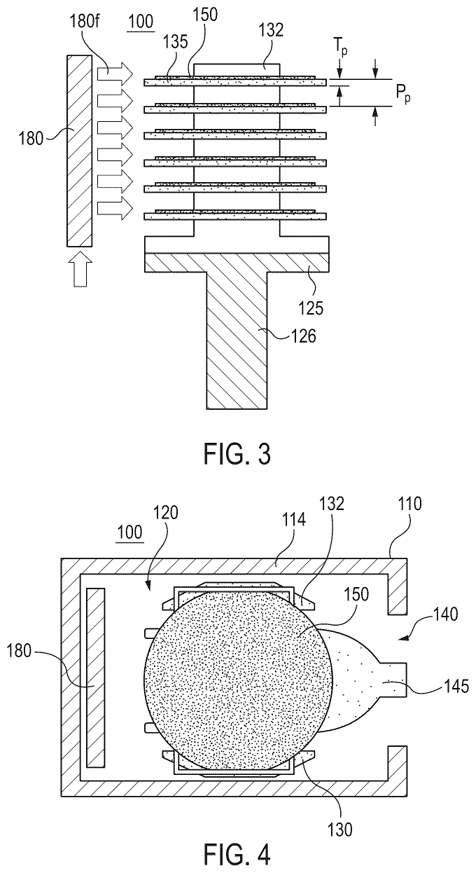

FIG. 2 illustrates a schematic cross-sectional view of a wafer processing chamber 100 configured to deposit films simultaneously on a plurality of substrate according to one or more embodiments of the disclosure. FIG. 3 illustrates a schematic cross-sectional view of a portion of the wafer processing chamber 100 illustrating gas flows to each substrate in the stack of substrates. FIG. 4 shows a schematic top view of a wafer processing chamber 100 illustrating loading/unloading of the wafers. The wafer processing chamber 100 has a chamber body 110 with a top 112, a sidewall 114 and a bottom 116. The chamber body 110 defines an inner chamber region 120 and an outer chamber region 122.

The wafer processing chamber 100 includes a wafer cassette assembly 130 inside the chamber body 110. The wafer cassette assembly 130 comprises at least two support columns 132 configured to hold a plurality of wafers 150, or a plurality of wafer supports 135 spaced along a height of the at least two support columns 132. The wafer cassette assembly 130 of some embodiments further comprises one or more of a floor 133 or ceiling (not shown). The embodiment illustrated in FIGS. 2 and 3 show six wafers 150 on six wafer supports 135. The skilled artisan will recognize that there can be any suitable number of wafers 150 and wafer supports 135 was indicated herein, for example 25 or more wafers. In some embodiments, there are in the range of 5 to 50 wafer supports 135, or in the range of 15 to 25 wafer supports 135.

The wafer cassette assembly 130 and wafer supports 135 can be made of any suitable material known to the skilled artisan. In some embodiments, the wafer cassette assembly 130 (including at least two support columns 132) and/or the plurality of wafer supports 135 comprise aluminum.

The wafer processing chamber 100 further comprises at least one lift pin assembly 170 comprising a plurality of lift pins 172. The plurality of lift pins 172 are arranged so that each of the plurality of wafer supports 135 comprises at least three lift pins 172. The skilled artisan will recognize that three points define a planar surface, and as the wafer 150 is a planar surface, three points of contact (i.e., by three lift pins) are used to prevent destabilization of the wafer 150 during loading/unloading operations.

The lift pins 172 (and optionally the lift pin assembly 170) can be made of any suitable material. In some embodiments, the plurality of lift pins 172 and/or at least one lift pin assembly 170 comprise a dielectric material. For example, suitable materials for the plurality of lift pins 172 and/or the at least one lift pin assembly 170 include, but are not limited to, ceramic.

As shown in FIG. 4, the sidewall 114 of the chamber body 110 comprises a slit valve 140 to allow a wafer 150 to be loaded or unloaded from the wafer processing chamber 100. In some embodiments, the slit valve 140 is located in the inner chamber region 120 of the chamber body 110 to load and unload wafers 150 from the wafer cassette 160. FIG. 4 illustrates a wafer 150 on a robot 145 extending through the open slit valve 140. The illustration shows the slit valve 140 without a door, however, the skilled artisan will recognize that the slit valve 140 of some embodiments has a door that can be opened and closed to isolate inner chamber region 120 from the conditions outside of the chamber body 110.

In the illustrated embodiment, the wafer cassette assembly 130 sits on a pedestal 125 connected to a pedestal lift assembly 126. The pedestal lift assembly 126 includes an actuator 127 (also referred to as a motor) configured to move the pedestal 125 along the height of the stack of wafers 150. Suitable actuators 127 include, but are not limited to, linear guides and servo motors or stepper motors. A bellows 128, or other suitable vacuum isolator, connects the pedestal lift assembly 126 with the chamber body 110 to maintain vacuum within the chamber body 110.

In some embodiments, the pedestal 125 acts as a cathode. For example, in a plasma-enhanced deposition process, the pedestal 125 acts as the cathode with a different component in the wafer processing chamber 100 acting as the anode to generate a plasma within the inner chamber region 120.

The at least one lift pin assembly 170 of some embodiments, further comprises a lift mechanism 175. The lift mechanism 175 can be used to move the at least one lift pin assembly 170 between the inner chamber region 120 and outer chamber region 122 of the chamber body 110. In the illustrated embodiment, the lift mechanism 175 includes an actuator 176 (also referred to as a motor). Suitable actuators 176 include, but are not limited to, linear guides and servo motors or stepper motors. In some embodiments, the actuator 176 is mounted to the pedestal lift assembly 126 and a bellows 178 (or other suitable vacuum isolator) connects the pedestal lift assembly 126 to the lift pin assembly 170 lift mechanism 175.

In the illustrated embodiment, the lift mechanism 175 includes a hollow shaft 177. The hollow shaft 177 of some embodiments is connected to a fore line or vacuum pump to maintain reduced pressure in the wafer processing chamber 100.

The wafer processing chamber 100 of some embodiments includes a gas injector 180. The gas injector 180 is not visible in the embodiment illustrated in FIG. 2 due to the angle of the view shown. However, a side view and top view showing the gas injector 180 can be found in FIGS. 3 and 4, respectively. The gas injector 180 is configured to provide a flow 180f of gas across the surface of the plurality of wafer supports 135. Specific features of the gas injector are shown and described with respect to FIGS. 6-14A-I.

In some embodiments, the pedestal 125 further comprises a heater (not shown). In some embodiments, the heater has one heating element. In some embodiments, there is more than one heating element. Multiple heating elements can be arranged in any suitable manner. In some embodiments, the heating elements are arranged in radial zone.

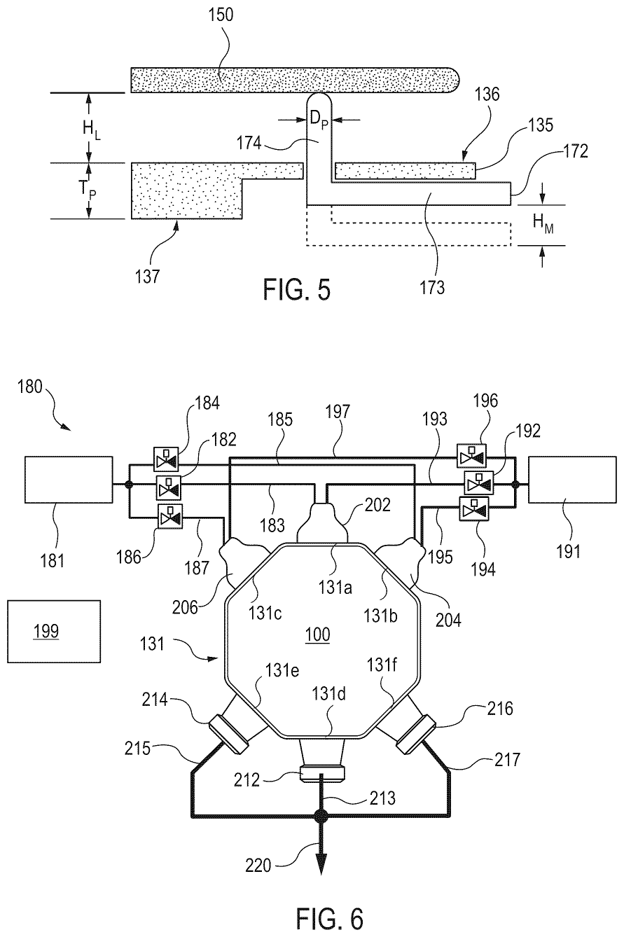

FIG. 5 illustrates a schematic partial cross-sectional view of a wafer 150 being lifted off the plurality of wafer supports 135 by a lift pin 172. Referring to FIGS. 3 and 5, the thickness T_{P} of the plurality of wafer supports 135 measured from the top surface 136 to the bottom surface 137 is in the range of 1 mm to 5 mm or in the range of 1.5 mm to 2.5 mm. The thickness is measured as the thickest portion of the plurality of wafer supports 135 that will be vertically oriented with a wafer 150 during processing. For example, the outer peripheral portions of the plurality of wafer supports 135 outside the diameter of the wafer 150 are not considered in this measurement.

In some embodiments, the pitch Pp between the top surfaces 136 of adjacent wafer supports 135 is in the range of 5 mm to 20 mm, or in the range of 7.5 mm to 15 mm, or in the range of 10 mm to 12 mm. In some embodiments, the pitch PP is greater than or equal to 5 mm, 6 mm, 7 mm, 8 mm or 9 mm, and less than or equal to 50 mm, 45 mm, 40 mm, 35 mm, 30 mm, 25 mm, 20 mm, or 15 mm.

Referring to FIG. 5, in some embodiments, the lift pin 172 comprises a pin arm 173 and a pin portion 174. In use, the height H_{M} that the lift pin 172 can move is in the range of 2 mm to 10 mm, or in the range of 3 mm to 8 mm, or in the range of 4 mm to 7 mm, or in the range of 5 mm to 6 mm. The height H_{M} that the lift pin 172 moves depends on, for example, the length of the pin portion of the lift pin 172 and the thickness of the robot 145 end effector. The height H_{L} that the wafer 150 is lifted above the top surface 136 of the plurality of wafer supports 135 during loading/unloading is equal to or less than the height H_{M} that the lift pin 172 can move.

The diameter D_{P} of the pin portion 174 of the lift pin 172 in some embodiments, is in the range of 1 mm to 10 mm, or in the range of 2 mm to 8 mm, or in the range of 3 mm to 6 mm. The contact end of the pin portion 174 can be any suitable shape including, but not limited to, squared, rounded or tapered.

One or more embodiments of the disclosure are directed to wafer cassette assemblies 130 with wafer supports 135 and at least one lift pin assembly 170. The wafer cassette assembly 130 illustrated includes two support columns 132 connected by the pedestal 125, or floor 133 of the wafer cassette assembly 130. The at least two support columns 132 are the base portion of the wafer cassette assembly 130 upon which the stack of at least one lift pin assembly 170 are positioned with a connector plate and/or connector (not shown) located at the top of the wafer cassette assembly 130.

In the illustrated embodiment the at least two support columns 132 of the wafer cassette assembly 130 are positioned on opposite sides of the plurality of wafer supports 135. This leaves an unsupported center portion of each plurality of wafer supports 135. The gap between the at least two support columns 132 can be used to allow for unrestricted access by the robot blades for loading/unloading operations.

Referring now to FIGS. 2 and 6-12, a wafer processing chamber 100 configured to deposit a film on a plurality of wafers is shown with the gas injector 180 shown in FIG. 3 in more detail in FIGS. 6-12. The wafer processing chamber 100 comprises the chamber body 110 having the top 112, the sidewall 114 and the bottom 116. The chamber body 110 defines an inner chamber region 120 and an outer chamber region 122.

The wafer processing chamber 100 further comprises the wafer cassette assembly 130 inside the chamber body 110, the wafer cassette assembly 130 assembly defining a peripheral surface 131 and a stack comprising at least two support columns 132 configured to hold a number of wafer supports 135 spaced along a height of the at least two support columns 132.

The wafer processing chamber further comprises a first multiple level gas injection assembly 202 located at a first peripheral location 131a of the wafer cassette assembly 130 and comprising a number of gas injection levels including a first gas injection level including a first gas manifold 202a configured to inject a first process gas to a first wafer support 135 and a second gas injection level including a first gas manifold 202c configured to inject the first process gas to a second wafer support. It will be understood that each of the number of gas injection levels can include a single gas manifold, for example a first level including the first gas manifold 202a and the second level comprising a first gas manifold 202c, both of the first gas manifold 202a and 202c configured to deliver a first process gas to different wafer supports in the wafer cassette assembly.

In a first specific embodiment shown in FIGS. 8-10, the wafer processing chamber 100 comprises a plurality of stacked gas manifolds 202a, 202b, 202c, 202d, 202e, 202f, 202g, 202h, 202i, 202j, 202k, 202l, 202m, 202n, 202o, 202p, 202q and 202r, which are configured to individually deliver a first process gas and a second process gas to the number of wafer supports 135 as provided herein according to one or more embodiments. In a more specific embodiment, a plurality of first gas manifolds 202a, 202c, 202e, 202g, 202i, 202k, 202m, 202o and 202q are configured to deliver a first process gas, and a plurality of second gas manifolds 202b, 202d, 202f, 202h, 202j, 202l, 202n and 202p are configured to deliver a second process gas to a plurality of wafer supports 135. Each stacked gas manifold comprises a first gas manifold stacked upon a second gas manifold with cover spacer 203 stacked upon the second gas manifold.

Thus, a first gas injection level comprises the first gas manifold 202a positioned and configured to deliver the first process gas and the second gas manifold 202b positioned and configured to deliver the second process gas to a first wafer support 135a positioned and configured to support a first wafer 150a. A second injection level comprises the first gas manifold 202c configured to deliver the first process gas and the second gas manifold 202d positioned and configured to deliver the second process gas to a second wafer support 135b configured to support a second wafer 150b. A third injection level comprises the first gas manifold 202e positioned and configured to deliver the first process gas and the second gas manifold 202f positioned and configured to deliver the second process gas to a third wafer support 135c configured to support a third wafer 150c.

A fourth injection level comprises the first gas manifold 202g positioned and configured to deliver the first process gas and the second gas manifold 202h positioned and configured to deliver the second process gas to a fourth wafer support 135d configured to support a fourth wafer 150d. A fifth injection level comprises the first gas manifold 202i positioned and configured to deliver the first process gas and the second gas manifold 202j positioned and configured to deliver the second process gas to a fifth wafer support 135e configured to support a fifth wafer 150e. A sixth injection level comprises the first gas manifold 202k positioned and configured to deliver the first process gas and the second gas manifold 202l positioned and configured to deliver the second process gas to a sixth wafer support 135f configured to support a fifth wafer 150f.

A seventh injection level comprises the first gas manifold 202m positioned and configured to deliver the first process gas and the second gas manifold 202n positioned and configured to deliver the second process gas to a seventh wafer support 135g configured to support a seventh wafer 150g. An eighth injection level comprises the first gas manifold 202o positioned and configured to deliver the first process gas and the second gas manifold 202p positioned and configured to deliver the second process gas to an eighth wafer support 135h configured to support an eighth wafer 150h. A ninth injection level comprises the first gas manifold 202q positioned and configured to deliver the first process gas and the second gas manifold 202r positioned and configured to deliver the second process gas to a ninth wafer support 135i configured to support a ninth wafer 150i.

It will be appreciated that while nine separate injection levels and nine separate wafer support 135a-i are shown in FIGS. 8-10 for the first multiple level gas injection assembly 202 located at a first peripheral location 131a of the wafer cassette assembly 130 and comprising a number of gas injection levels, in the embodiment shown, there is a second multiple level gas injection assembly 204 located at a second peripheral location 131b of the wafer cassette assembly 130 and a third multiple level gas injection assembly 206 located at a third peripheral location 131c of the wafer cassette assembly 130. In the specific embodiments shown, the wafer cassette assembly 130 is in the shape of an octagon and the second multiple level gas injection assembly 204 is located at an angle of 45 degrees away from the first multiple level gas injection assembly 202. Likewise the third multiple level gas injection assembly 206 is located at an angle of 45 degrees away from the first multiple level gas injection assembly 202. Therefore, the second multiple level gas injection assembly 204 and the third multiple level gas injection assembly 206 are located at an angle of 90 degrees from each other. As used herein, the degrees away from the respective multiple level gas injection assemblies refers to a radial arc from a centerline of the respective multiple level gas injection assembly viewing the wafer cassette assembly 130 and the multiple level gas injection assemblies 202, 204 and 206 from a top plan view. The angular separation of adjacent multiple level gas injection assemblies, for example 202 and 204 and 202 and 206 can vary between 10 and 60 degrees, 20 and 45 degrees and 35 and 45 degrees.

FIG. 8 shows the first multiple level gas injection assembly 202 and the second multiple level gas injection assembly 204 respectively positioned at the first peripheral location 131a and the second peripheral location 131b. The third multiple level gas injection assembly 206 is not sown in FIG. 8 so that the wafer cassette assembly 130 and the wafers 150 and wafer supports 135 can be seen. Additionally, in the isometric view shown in FIG. 8, only the seventh, eighth and ninth injection levels are shown. Accordingly, FIG. 8 shows a seventh injection level of the second multiple level gas injection assembly 204 comprising a gas manifold 204m positioned and configured to deliver the first process gas and a second gas manifold 204n positioned and configured to deliver the second process gas to the seventh wafer support 135g configured to support the seventh wafer 150g. The second multiple level gas injection assembly 204 further comprises an eighth injection level comprising a first gas manifold 204o positioned and configured to deliver the first process gas and the second gas manifold 204p positioned and configured to deliver the second process gas to the eighth wafer support 135h configured to support the eighth wafer 150h. The second multiple level gas injection assembly 204 further comprises a ninth injection level comprising a first gas manifold 204q positioned and configured to deliver the first process gas and a second gas manifold 204r positioned and configured to deliver the second process gas to the ninth wafer support 135i configured to support the ninth wafer 150i.

It will be appreciated that each of the multiple level gas injection assemblies 202, 204 and 206 will be similarly configured to deliver gas to the number of wafer supports 135 in the cassette assembly. Therefore, while there are nine wafer supports 135a-i shown in the Figures, according to one or more embodiments, the multiple level gas injection assemblies 202, 204, 206 can contain any number of gas injection levels in a range of from 4 to 50 gas injection levels, for example, 5, 6, 7, 8, 9 10, 12, 15, 20, 25, 30, 35, 40, 45 or 50 gas injection levels configured to deliver at least a first process gas to a number of wafer supports 135 in a range of from 4 to 50 wafer supports 135, for example, 5, 6, 7, 8, 9 10, 12, 15, 20, 25, 30, 35, 40, 45 or 50 wafer supports 135. In specific embodiments, each gas injection level of each of the multiple level gas injection assemblies will comprise a first gas manifold configured to deliver a first process gas and a second gas manifold configured to deliver a second process gas. According to one or more embodiments, each gas injection level will be separated by a cover spacer 203 as shown in FIGS. 8-11.

In some embodiments, each of the first multiple level gas injection assembly 202, the second multiple level gas injection assembly 204, and the third multiple level gas injection assembly 206 comprises a number of gas injection levels that is less than or equal to the number of wafer supports 135. In specific embodiments, the number gas injection levels and the number of wafer supports is equal for each of the multiple level gas injection assemblies. In some embodiments, each of the first gas injection level and the second gas injection level of the first multiple level gas injection assembly 202, the first gas injection level and the second gas injection level of the second multiple level gas injection assembly 204 and the first gas injection level and the second gas injection level of the third multiple level gas injection assembly 208 further includes a second gas manifold stacked upon each of the first gas manifolds and configured to inject the second process gas to the first wafer support and the second wafer support.

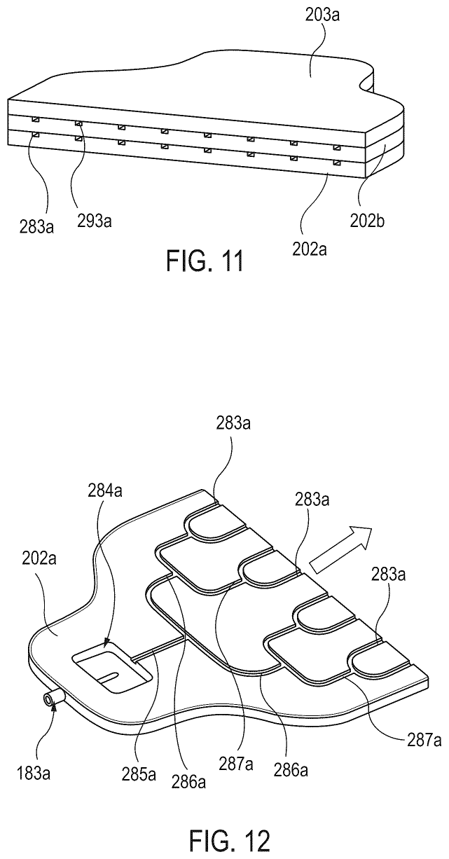

As shown in FIG. 11, the first gas manifold 202a comprises first gas outlets 283a and a second gas manifold 202b stacked upon the first gas manifold 202a comprises second gas outlets 293. The first gas outlets 283a and second gas outlets 293a are included in each of levels of the multiple level gas injection assemblies 202, 204 and 206.

Specific features of the first gas manifold 202a are shown in FIG. 12, and these features may be identical for each of the gas manifolds described herein. The multiple level gas injection assembly 202 comprises a gas manifold inlet 183a, a reservoir 284a in fluid communication with the gas manifold inlet 183a. The gas manifold may further comprise a first channel 285a in fluid communication with the reservoir 284a, which may branch out to a first pair of channels 286a, and each of the first pair of channels 286a may branch out to two pairs of channels 287a. The two pairs of channels are in fluid communication with the first gas outlets 283a. The reservoir 284a has a depth that is greater than the first channel 285, which is configured to regulate and minimize back pressure and/or gas surg or overpressure issues.

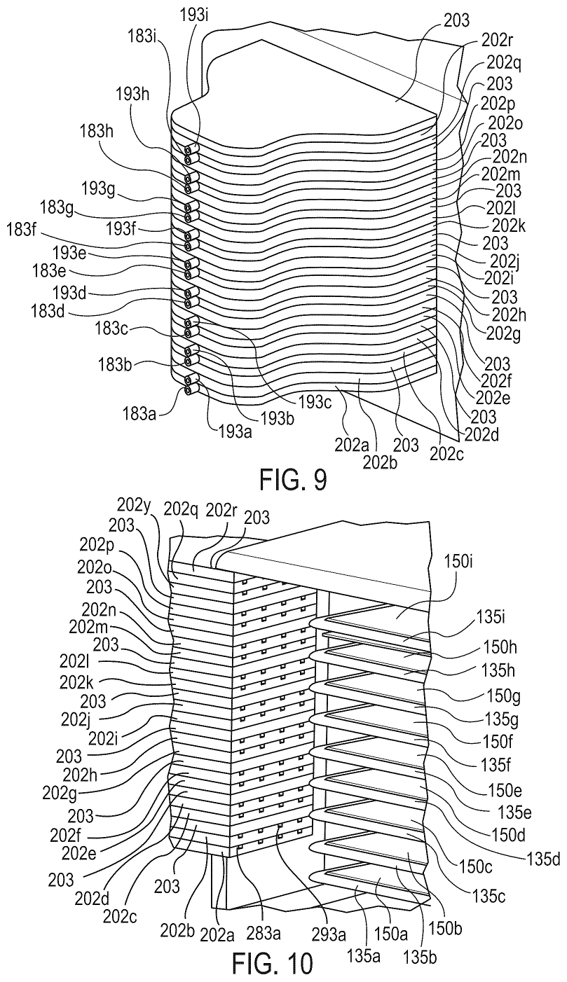

Referring back to FIG. 9, it will be appreciated that each of the gas manifolds are configured similarly to the first gas manifold 202a shown in FIG. 12. Thus, the first gas manifold 202c has a first gas inlet 183b, the first gas manifold 202e has a first gas inlet 183c, the first gas manifold 202g has a first gas inlet 183d, the first gas manifold 202i has a first gas inlet 183e, the first gas manifold 202k has a first gas inlet 183f, the first gas inlet 202m has a first gas inlet 183g, the first gas manifold 202o has a first gas inlet 183h and the first gas manifold 202q has a first gas inlet 183i. Each of these respective gas inlets are in fluid communication with the first process gas supply 181. Likewise, a plurality of second gas manifolds 202b, 202d, 202f, 202h, 202j, 202l, 202n, 202p and 202r are respectively connected to the second process gas supply via a plurality second gas inlets 193a, 193b, 193c, 193d, 193e, 193f, 193g, 193h and 193i.

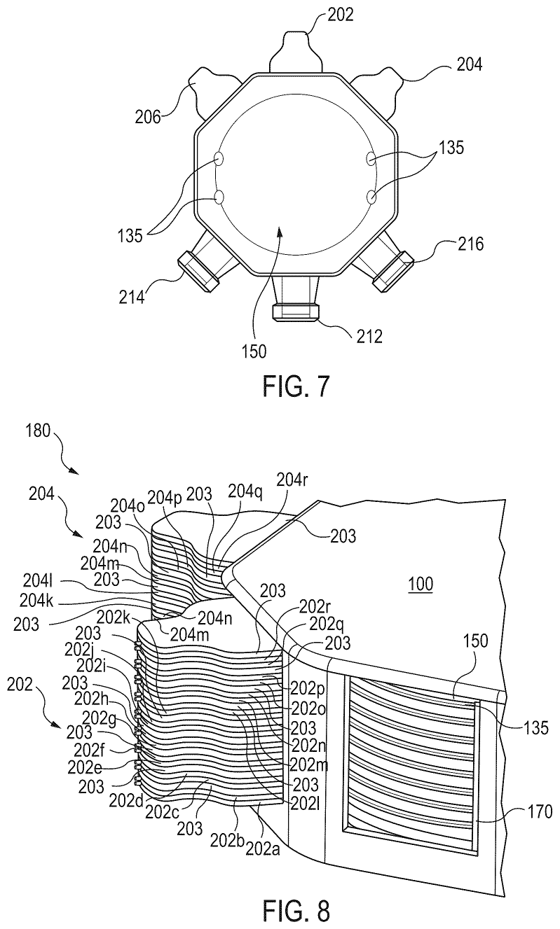

Referring to FIGS. 6 and 7, each of the first gas injection levels and the second gas injection levels of the of the first multiple level gas injection assembly 202, the second multiple level gas injection assembly 204 and the third multiple level gas injection assembly 206 comprise a first gas outlet 212 located at a fourth peripheral location 131d of the wafer cassette assembly 130, a second gas outlet 214 and a third gas outlet 216.

The wafer processing chamber of claim 11, wherein each of the first gas outlets are located at a fourth peripheral location 131d of the wafer cassette assembly 130, each of the second gas outlets 214 are located at a fifth peripheral location 131e of the wafer cassette assembly 130, and each of the third gas outlets 216 are located at a sixth peripheral 131f location of the wafer cassette assembly 130. In one or more embodiments, the fourth peripheral location 131d is located diametrically opposite the first peripheral location 131, the fifth peripheral location 131e is located diametrically opposite the second peripheral location 131b and the sixth peripheral location 131f is located opposite the third peripheral location 131c. According to one or more embodiments, diametrically opposite refers to a center line of the respective gas outlets 212, 214 and 216 respectively being approximately 180 degrees from a centerline of the respective first, second and third multiple level gas injection assemblies 202, 204 and 206. It will be appreciated that the angular relationship can vary by plus or minus 10 degrees, and therefore, the first gas outlet 212 may be at an angle in a range of from 170 to 190 degrees away from the first multiple level gas assembly 202. The second gas outlet 214 may be at an angle in a range of from 170 to 190 degrees away from the second multiple level gas injection assembly 204. The third gas outlet 216 may be at an angle in a range of from 170 to 190 degrees from the third multiple level gas injection assembly 206.

Referring now to FIG. 6, the wafer processing chamber 100 of some embodiments comprises a plurality of gas control valves configured to control flow of the first process gas and the second process gas to the first multiple level gas injection assembly 202, the second multiple level gas injection assembly 204 and the third multiple level gas injection assembly 206. Thus, a first process gas supply 181, which may be in the form of a gas container, includes a first gas control valve 182 in fluid communication with the first process gas supply 181 that is configured to regulate a gas pressure and flow rate to the first multiple level gas injection assembly 202 via a first gas supply line 183. A second gas control valve 184 in fluid communication with the first process gas supply 181 is configured to regulate a gas pressure and flow rate to the second multiple level gas injection assembly 204 via a second gas supply line 185. Likewise, a third gas control valve 186 in fluid communication with the first process gas supply 181 is configured to regulate a gas pressure and flow rate to the third multiple level gas injection assembly 206 via a third gas supply line 187.

Similarly, there is a second process gas supply 191, which may be in the form of a gas container, which is in fluid communication with a fourth gas control valve 192 in fluid communication with the second process gas supply 191 that is configured to regulate a gas pressure and flow rate to the first multiple level gas injection assembly 202 via a fourth gas supply line 193. A fifth gas control valve 194 in fluid communication with the second process gas supply 191 is configured to regulate a gas pressure and flow rate to the second multiple level gas injection assembly 204 via a fifth gas supply line 195. Likewise, a sixth gas control valve 196 in fluid communication with the second process gas supply 191 is configured to regulate a gas pressure and flow rate to the third multiple level gas injection assembly 206 via a sixth gas supply line 197. A controller 199 is configured to control opening and closing of the gas control valves 182, 184, 186, 192, 194, and 196. The controller 199 can communicate with the gas valves via a wired or wireless connection.

The first gas outlet 212 is in fluid communication with a first gas outlet line 213, the second gas outlet 214 is in fluid communication with a second gas outlet line 215 and the third gas outlet 216 is in fluid communication with a third gas outlet line 217. The gas outlet lines 213, 215 and 217 are in fluid communication with an exhaust line 220, which may be connected to a pump to remove the gases to an exhaust system (not shown).

Another aspect of the disclosure pertains to a method of simultaneously forming a film on a plurality of wafers 150 vertically spaced and stacked in a wafer cassette of a multiple substrate processing chamber, for example as described with respect to FIG. 12 herein.

In one or more embodiments, the method comprises flowing the first process gas through the first multiple level gas injection assembly 202 of the wafer processing chamber 100 described herein. In some embodiments, the method comprises flowing the first process gas through the second multiple level gas injection assembly 204 and the third multiple level gas injection assembly 206. Additional embodiments further comprise flowing the second process gas through the first multiple level gas injection assembly 202, the second multiple level gas injection assembly 204 and the third multiple level gas injection assembly 206.

Embodiments of the method may further comprise controlling the flow of the first process gas and the second process gas by controlling the plurality of gas control valves described herein. In some embodiments, the method comprises sequentially controlling the flow of the first process gas and the second process gas during an atomic layer deposition film formation process.

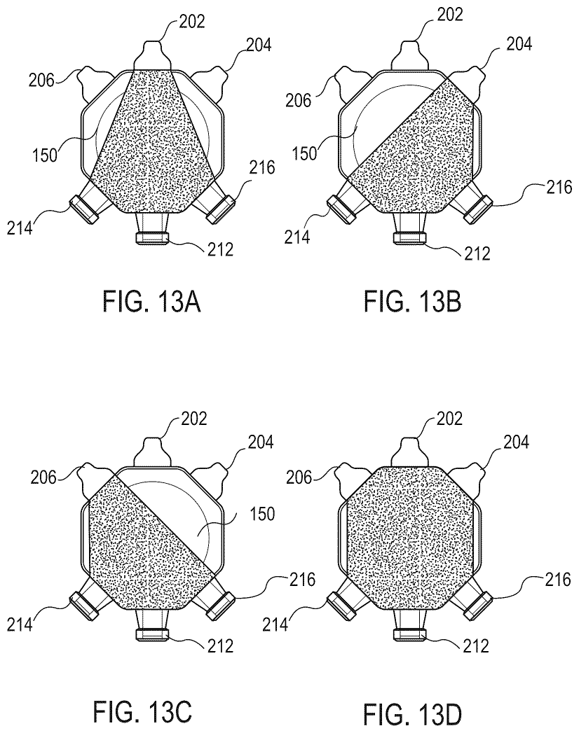

Referring now to FIG. 13, a first embodiment is shown where the first gas control valve 182 and the fourth gas control valve 192 are opened to cause flow through only the first multiple level gas injection assembly 202, while gas is allowed to flow through the first gas outlet 212, the second gas outlet 214 and the third gas outlet 216. As can be seen the gas shown in stippling is not uniform across the wafer 150.

In FIG. 13B, gas is flowed through only the second multiple level gas injection assembly 204 by controlling the appropriate gas control valves, while gas is allowed to flow through the first gas outlet 212, the second gas outlet 214 and the third gas outlet 216. As can be seen the gas shown in stippling is not uniform across the wafer 150. FIG. 13C shows a flow pattern where only gas is flowed through the third multiple level gas injection assembly 206, while gas is allowed to flow through the first gas outlet 212, the second gas outlet 214 and the third gas outlet 216. As can be seen the gas shown in stippling is not uniform across the wafer 150.

However, in FIG. 13D, when the appropriate gas control valves are opened and gas is flowed through each of the first multiple level gas injection assembly 202, the second multiple level gas injection assembly 204 and the third multiple level gas injection assembly 206, uniform flow distribution of the process gases is achieved across the substrate.

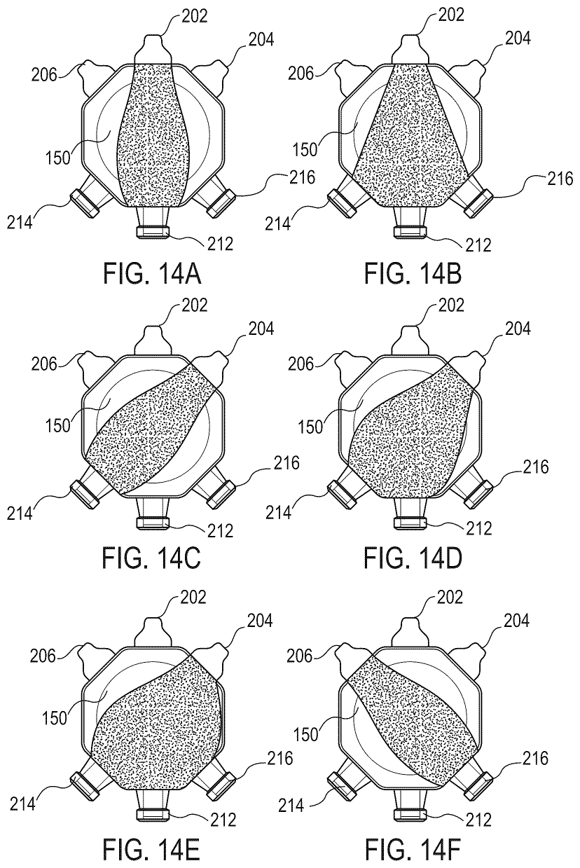

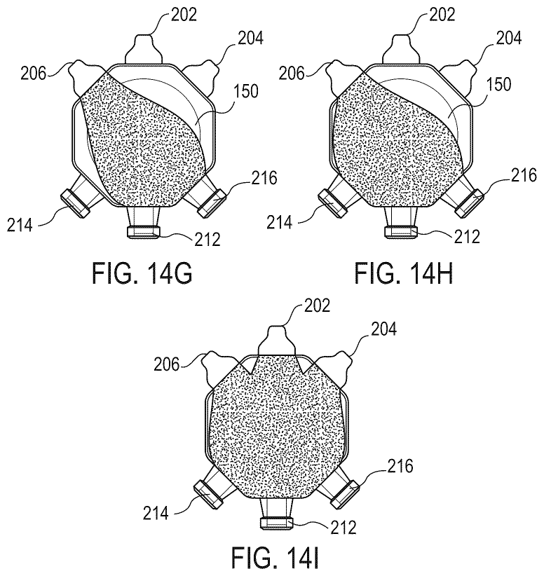

FIGS. 14A-I further illustration different flow control patterns that can be achieved by controlling flow through the gas inlets and outlets by controlling the flow control valve with the controller 199. FIG. 14A shows a flow pattern through the only the first multiple level gas injection assembly 202 and the first gas outlet 212. FIG. 14 shows flow through only the first multiple level gas injection assembly 202 and the first gas outlet 212, the second gas outlet 214, and the third gas outlet 216, with greater coverage of the substrate.

FIG. 14C shows gas flow through only the second multiple level gas injection assembly 204 and the second gas outlet 214. Gas distribution over the surface of the wafer 150 is improved in FIG. 14D by flowing through the second gas outlet 214 and third gas outlet, and in FIG. 14E, gas distribution is further improved by flowing gas through the first gas outlet 212, the second gas outlet 214 and the third gas outlet 216.

In FIG. 14G, gas is flowed only through only the third multiple level gas injection assembly 206 and the third gas outlet 216. In FIG. 14G, flow distribution is improved by flowing gas through the first gas outlet 212, and gas flow distribution is further improved in FIG. 14H by flowing gas through the second gas outlet 214. In FIG. 14H, the gas flow is distributed evenly by flowing the gas through the first multiple level gas injection assembly 202, the second multiple level gas injection assembly 204 and the third multiple level gas injection assembly 206 and through the first gas outlet 212, the second gas outlet 214 and the third gas outlet 216 to achieve uniform gas flow distribution across the wafer 150.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A wafer processing chamber configured to deposit a film on a plurality of wafers, the wafer processing chamber comprising:
a chamber body having a top, sidewall and bottom defining an inner chamber region and an outer chamber region;
a wafer cassette assembly inside the chamber body, the wafer cassette assembly defining a peripheral surface and a stack comprising at least two support columns configured to hold a number of wafer supports spaced along a height of the at least two support columns; and
a first multiple level gas injection assembly located at a first peripheral location of the wafer cassette assembly and comprising a number of gas injection levels including a first gas injection level including a first gas manifold configured to inject a first process gas to a first wafer support and a second gas injection level including a first gas manifold configured to inject the first process gas to a second wafer support.

2. The wafer processing chamber of claim 1, the wafer processing chamber further comprising a second multiple level gas injection assembly located at a second peripheral location of the wafer cassette assembly and spaced apart from the first peripheral location, the second multiple level gas injection assembly comprising at least two gas injection levels including a first gas injection level including a first gas manifold configured to inject the first process gas to the first wafer support and a second gas injection level including a first gas manifold configured to inject the first process gas to the second wafer support.

3. The wafer processing chamber of claim 2, the wafer processing chamber further comprising a third multiple level gas injection assembly located at a third peripheral location of the wafer cassette assembly and spaced apart from the second peripheral location, the second multiple level gas injection assembly comprising at least two gas injection levels including a first gas injection level including a first gas manifold configured to inject the first process gas to the first wafer support and a second gas injection level including a first gas manifold configured to inject the first process gas at the second wafer support.

4. The wafer processing chamber of claim 3, wherein and each of the first multiple level gas injection assembly, the second multiple level gas injection assembly, and the third multiple level gas injection assembly comprises a number of gas injection levels that is less than or equal to the number of wafer supports.

5. The wafer processing chamber of claim 4, wherein the number of gas injection levels is equal to the number of wafer supports.

6. The wafer processing chamber of claim 5, wherein the number of gas injection levels and the number of wafer supports is at least ten.

7. The wafer processing chamber of claim 3, each of the first gas injection level and the second gas injection level of the first multiple level gas injection assembly, the first gas injection level and the second gas injection level of the second multiple level gas injection assembly and the first gas injection level and the second gas injection level of the third multiple level gas injection assembly further includes a second gas manifold stacked upon each of the first gas manifolds and configured to inject a second process gas to the first wafer support and the second wafer support.

8. The wafer processing chamber of claim 7, wherein the number of gas injection levels is equal to the number of wafer supports.

9. The wafer processing chamber of claim 8, wherein the number of gas injection levels and the number of wafer supports is at least ten.

10. The wafer processing chamber of claim 9, wherein each of the number of gas injection levels of each of each of the first multiple level gas injection assembly, the second multiple level gas injection assembly and the third multiple level gas injection assembly comprise a second gas manifold stacked each of the first gas manifolds and configured to inject the second process gas to each of the number of gas injection levels.

11. The wafer processing chamber of claim 7, wherein each of the first gas injection levels and the second gas injection levels of the of the first multiple level gas injection assembly, the second multiple level gas injection assembly and the third multiple level gas injection assembly comprise a first gas outlet located at a fourth peripheral location of the wafer cassette assembly, a second gas outlet and a third gas outlet.

12. The wafer processing chamber of claim 11, wherein each of the first gas outlets are located at a fourth peripheral location of the wafer cassette assembly, each of the second gas outlets are located at a fifth peripheral location of the wafer cassette assembly, and each of the third gas outlets are located at a sixth peripheral location of the wafer cassette assembly.

13. The wafer processing chamber of claim 12, wherein the fourth peripheral location is located diametrically opposite the first peripheral location, the fifth peripheral location is located diametrically opposite the second peripheral location and the sixth peripheral location is located opposite the third peripheral location.

14. The wafer processing chamber of claim 13, further comprising a plurality of gas control valves configured to control flow of the first process gas and the second process gas to the first multiple level gas injection assembly, the second multiple level gas injection assembly and the third multiple level gas injection assembly.

15. The wafer processing chamber of claim 14, further comprising a controller configured to control opening and closing of the gas control valves.

16. A method of simultaneously forming a film on plurality of wafers comprising flowing the first process gas through the first multiple level gas injection assembly of the wafer processing chamber of claim 15.

17. The method of claim 16, further comprising flowing the first process gas through the second multiple level gas injection assembly and the third multiple level gas injection assembly.

18. The method of claim 17, further comprising flowing the second process gas through the first multiple level gas injection assembly, the second multiple level gas injection assembly and the third multiple level gas injection assembly.

19. The method of claim 18, further comprising controlling flow of the first process gas and the second process gas by controlling the plurality of gas control valves.

20. The method of claim 19, further comprising sequentially controlling the flow of the first process gas and the second process gas during an atomic layer deposition film formation process.
